(19) United States
(12) Patent Application Publication
(10) Pub. No.: US 2017/0271299 A1
(43) Pub. Date: Sep. 21, 2017

(54) ANISOTROPIC CONDUCTIVE FILM (ACF), BONDING STRUCTURE, AND DISPLAY PANEL, AND THEIR FABRICATION METHODS

(71) Applicant: BOE TECHNOLOGY GROUP CO., LTD, Beijing (CN)

(72) Inventors: HONG LI, Beijing (CN); WEI HUANG, Beijing (CN); LIQIANG CHEN, Beijing (CN)

(21) Appl. No.: 15/305,506

(22) PCT Filed: Oct. 29, 2015
(86) PCT No.: PCT/CN2015/093235

§ 371 Date: Oct. 20, 2016

(51) Int. Cl. H01L 23/00; H01L 23/498; H01L 27/12

(52) U.S. Cl. CPC H01L 24/83; H01L 27/124; H01L 23/4985; H01L 24/29; H01L 24/92; H01L 24/73; H01L 2224/29499; H01L 2224/29393; H01L 2924/01006; H01L 2224/2929; H01L 2224/29424; H01L 2224/29439; H01L 2224/29444; H01L 2224/29447; H01L 2224/29455; H01L 2224/29466; H01L 2224/73204; H01L 2224/83874; H01L 2224/83851; H01L 2224/83887; H01L 2224/9211; H01L 27/3276

(57) ABSTRACT

An anisotropic conductive film (ACF), a bonding structure, and a display panel, and their fabrication methods are provided. The ACF includes a resin gel and a plurality of conductive particles dispersed in the resin gel. The plurality of conductive particles is aligned and connected, in response to an electric field, to form a conduction path in the resin gel. The bonding structure includes the anisotropic conductive film (ACF) sandwiched between first and second substrates. The display panel includes the bonding structure.

### FIELD OF THE DISCLOSURE

The present disclosure generally relates to the field of the display technologies and, more particularly, relates to an anisotropic conductive film (ACF), a bonding structure, and a display panel, and their fabrication methods.

### BACKGROUND

Conventional anisotropic conductive film used for forming a bonding structure between a display panel and a circuit film may include a thermo-pressing process at a high temperature of at least about 200° C., so that the circuit film and the display panel may be able to electrically connect each other.

Such thermo-pressing process at a high temperature may expand the volume of the circuit film to cause electrodes on the circuit film to be miss-aligned with electrodes on panel substrate. Often, during the thermo-pressing process, the applied pressure may need to be highly controlled to avoid insufficient or uneven pressure. Such insufficient or uneven pressure may adversely affect function of the conductive particles and the display device may have abnormal display or may not have any display on screen.

The disclosed anisotropic conductive film (ACF), bonding structure, and display panel, and their fabrication methods may at least partially alleviate one or more problems set forth above and other problems.

### BRIEF SUMMARY OF THE DISCLOSURE

One aspect of the present disclosure includes an anisotropic conductive film (ACF). The ACF includes a resin gel and a plurality of conductive particles dispersed in the resin gel. The plurality of conductive particles is aligned and connected, in response to an electric field, to form a conduction path in the resin gel.

Optionally, the resin gel includes one or more materials selected from a group of epoxy acrylates, urethane acrylates, polyester acrylates, polyether acrylates, acrylated polyacrylic resin, unsaturated polyester resin, and acrylate monomers.

Optionally, the conductive particles include carbon-based particles selected from a group of carbon black, carbon fibers, and carbon nanotubes.

Optionally, the conductive particles are in a form of cones, pyramids, shafts, pillars, wires, rods, needles, and spheres.

Optionally, the conductive particles have a circular or polygonal cross-section.

Optionally, the conductive particle includes an insulation material core, and a metal material encapsulating the insulation material core. The metal material includes one or more metal elements selected from a group of Cu, Ag, Ni, Ti, Al, and Au.

Optionally, the conductive particles are dispersed in the resin gel having a particle concentration ranging from about 5,000 pcs/mm³ to about 10,000 pcs/mm³.

Another aspect of the present disclosure includes a bonding structure including the disclosed anisotropic conductive film. The resin gel is configured between a first substrate and a second substrate. The first substrate has pad electrodes thereon. The second substrate has bump electrodes thereon. The plurality of conductive particles in the resin gel provides the conduction path in the resin gel between one pad electrode of the first substrate and one bump electrode of the second substrate.

Optionally, the resin gel is UV-curable to bond the first substrate with the second substrate.

Optionally, the one bump electrode faces the one pad electrode face and is aligned with the one pad electrode.

Another aspect of the present disclosure includes a display panel including the disclosed bonding structure. The display panel includes a liquid crystal display, a field emission display, a plasma display, and an organic light emitting diode display device.

Optionally, the first substrate is a panel substrate, and the pad electrodes are located in a panel bonding area of the panel substrate.

Optionally, the second substrate is a chip-on-film (COF) substrate or a flexible printed circuit (FPC) substrate.

Another aspect of the present disclosure includes a method for forming a bonding structure by providing a first substrate having pad electrodes thereon. A resin gel, containing conductive particles therein, is coated to cover the pad electrodes on the first substrate. A second substrate, having bump electrodes thereon, is provided on the resin gel. The bump electrodes face the pad electrodes. An electric field is applied to align and connect the conductive particles in the resin gel to form a conduction path between the bump electrodes and the pad electrodes.

Optionally, the resin gel is cured to bond the first substrate with the second substrate by a UV-curing process. Optionally, the UV-curing process is performed at a room temperature and at a wavelength ranging from about 100 nm to about 400 nm.

Optionally, the first substrate is a panel substrate. The pad electrodes are located in a panel bonding area of the panel substrate. The resin gel containing the conductive particles is coated on the panel bonding area to cover the pad electrodes.

Optionally, the step of providing a second substrate having bump electrodes thereon on the resin gel further includes: aligning the bump electrodes with the pad electrodes, and performing a preliminary pressing process, such that the second substrate and the resin gel are in direct contact.

Optionally, the electric field is controlled to have an electric field strength in a range from about 0.5 KV/mm to about 2 KV/mm.

Other aspects of the present disclosure can be understood by those skilled in the art in light of the description, the claims, and the drawings of the present disclosure.

### BRIEF DESCRIPTION OF THE DRAWINGS

The following drawings are merely examples for illustrative purposes according to various disclosed embodiments and are not intended to limit the scope of the disclosure.

FIGS. 1-5 illustrate exemplary structures corresponding to certain stages when manufacturing a bonding structure of a display panel according to various disclosed embodiments; and

FIGS. 6a-6d illustrate movement of conductive particles under an electric field in a resin gel between pad and bump electrodes according to various disclosed embodiments.

### DETAILED DESCRIPTION

For those skilled in the art to better understand the technical solution of the disclosure, reference will now be made in detail to exemplary embodiments of the disclosure, which are illustrated in the accompanying drawings. Wherever possible, the same reference numbers will be used throughout the drawings to refer to the same or like parts.

An anisotropic conductive film (ACF), a bonding structure, and a display panel, and their fabrication methods are provided. For example, the ACF may include a resin gel and a plurality of conductive particles dispersed in the resin gel. The plurality of conductive particles may be aligned and connected, in response to an electric field, to form a conduction path in the resin gel. An exemplary bonding structure may include the anisotropic conductive film (ACF) sandwiched between first and second substrates. An exemplary display panel may include the bonding structure.

The exemplary display panel may include a display panel used in, for example, a liquid crystal display, a field emission display, a plasma display, an organic light emitting diode (OLED) display device, or any suitable display device.

Note that although the disclosed bonding structure is described herein primarily related with display panels, the disclosed bonding structure may also be used in any suitable devices that include interconnections or connection path between different layers and/or different substrates. Such devices may include, for example, integrated circuit (IC) chips.

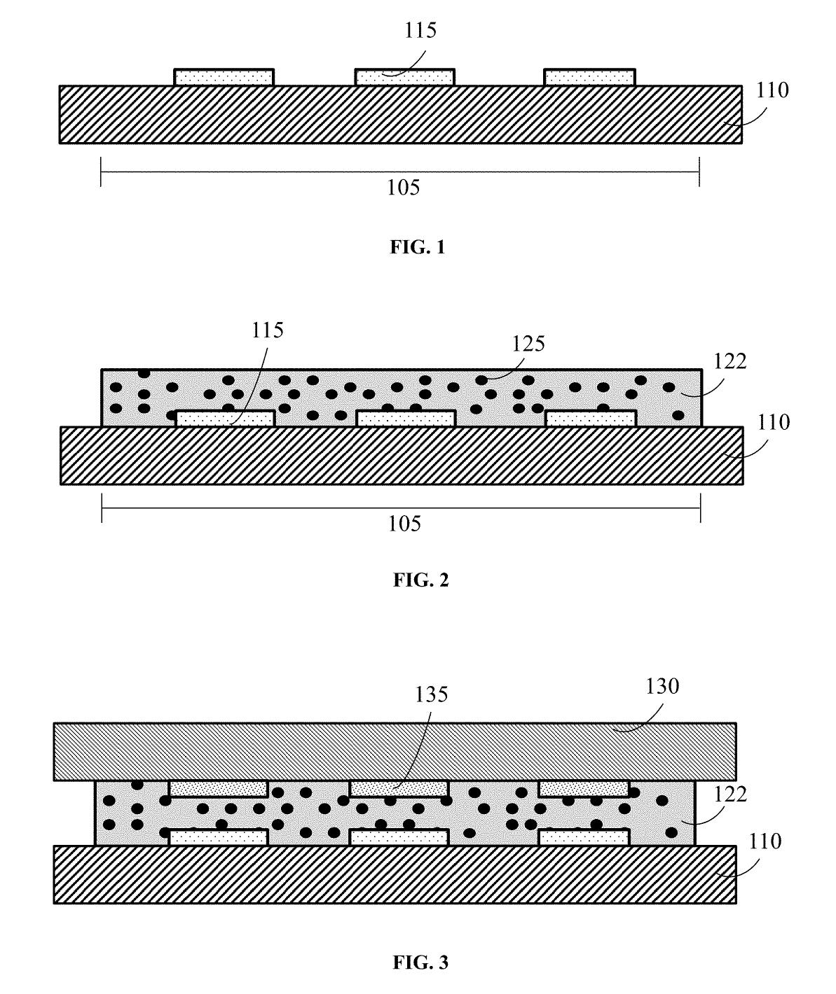

In FIG. 1, a first substrate, such as a panel substrate 110, is provided. One or more pad electrodes 115 are formed on the panel substrate 110.

The panel substrate 110 may be made of an optically transparent material having a high heat and chemical resistance. For example, the panel substrate 110 may be a thin film substrate formed of one or more materials selected from a group of polyimide (PI), polymethylmethacrylate (PMMA), polyethyleneterephthalate (PET), polycarbonate (PC), acryl, triacetylcellulose (TAC), and/or polyethersulfone (PES).

The panel substrate 110 may be a substrate for a display panel used in a display device. For example, the panel substrate 110 may be divided into a display area for displaying an image, and a non-display area. The non-display area may be an area where visibility may be reduced or even prevented using a black matrix, or the like. The non-display area may be used to hide a wire pattern and a driving circuit coupled to pixels in the display area.

The pad electrodes 115 may be located in a panel bonding area 105 of the non-image area of the panel substrate 110. The pad electrodes 115 may be electrically connected or coupled to an external driving circuit or any suitable external circuit. The pad electrodes 115 may be made of a conductive material to receive an electric signal, such as a control signal.

In one embodiment, the panel substrate 110 may be an array substrate of a display panel. For example, the display panel may be an OLED (not shown) panel including a panel substrate, based on which drive transistors and organic light emission elements may be formed. In an exemplary top-gate type OLED device, the OLED panel may possibly include a buffer layer, a semiconductor layer, a gate insulation film, gate electrodes, an interlayer insulation film, source and drain electrodes, and/or a passivation layer, all of which are sequentially formed on the panel substrate. In this case, the pad electrodes 115 may be formed on any possible layer of the array substrate of this OLED panel.

In FIG. 2, a resin gel 122 having conductive particles 125 dispersed therein may be coated on the panel bonding area 105 to at least cover the pad electrodes 115.

The resin gel 122 may be “liquid-like” to at least allow particle movement within the resin gel. On the other hand, the resin gel 122 may provide sufficient strength be coated on the panel substrate 110.

The resin gel 122 may be made of UV-curable materials and may be insulation materials. In one embodiment, such UV-curable materials may contain double bond to allow polymerization and/or crosslinking reactions under UV light.

The resin gel 122 may include one or more materials selected from a group including epoxy acrylates, urethane acrylates, polyester acrylates, polyether acrylates, acrylated polyacrylic resin, unsaturated polyester resin, and/or any suitable resins. In some embodiments, the resin gel 122 may include, for example, a variety of acrylate monomers with single or multiple functional groups.

When illuminated by UV light, polymerization and/or crosslinking reactions may occur to the UV-curable materials of the resin gel 122. Such reactions may be initiated by free radicals produced due to photon energy transferred via photoinitiator under UV light.

The conductive particles 125 may be formed of a material capable of transferring electric signals. Various types of conductive particles may be used. For example, the conductive particles 125 may be carbon-based particles including, carbon black, carbon fibers, and/or carbon nanotubes.

For example, the carbon nanotubes may include single wall carbon nanotubes (SWCNTs), double-wall carbon nanotubes (DWCNTs), multi-wall carbon nanotubes (MWCNTs), and their various functionalized and derivatized fibril forms such as carbon nanofibers. The carbon nanotubes can have an inside diameter and an outside diameter. The conductive particles 125 may have at least one dimension less than 1 micrometer, or less than 500 nanometers, or less than 100 nanometers. The conductive particles 125 may have an elongated structure in a form of cones, pyramids, shafts, pillars, wires, rods, and/or needles. In some cases, the conductive particles 125 may be spherical particles. The conductive particles 125 may have various cross-sectional shapes including, for example, a circular or polygonal cross-section.

In one embodiments, substantially all of the conductive particles 125 in the resin gel 122 may be uniformly shaped or having similar shapes/dimensions. In some embodiments, the conductive particles 125 may include an insulation material core, and a metal material encapsulating the insulation material core. The metal material may include one or more metal elements selected from a group of Cu, Ag, Ni, Ti, Al, and Au.

In FIG. 3, a second substrate 130 having bump electrodes 135 thereon may be provided on the resin gel 122, such that the resin gel 122 containing the conductive particles 125 is located between the panel substrate 110 and the second substrate 130.

The second substrate 130 may be mounted with a driving circuit or a driving chip. For example, the second substrate 130 may be a chip-on-film (COF) substrate, having a driving chip used to generate driving signals to drive the display panel by reacting with various control signals applied through the second substrate 130. The driving signal generated from the driving chip in the second substrate 130 is applied to, e.g., a gate line and to a data line of the panel substrate 110, and then drives the display panel to operate. In some embodiments, the second substrate 130 may be a flexible printed circuit (FPC) substrate having bump electrodes.

The bump electrodes 135 are positioned on the second substrate 130 corresponding to the pad electrodes 115 of the panel substrate 110. In FIG. 3, the bump electrodes 135 on the second substrate 130 are configured to face the pad electrodes 115 on the panel substrate 110.

The bump electrodes 135 may be made of a conductive material to transmit the control signal. In one embodiment, the bump electrodes 135 and the pad electrodes 115 may be made of same or similar conductive materials. For example, the conductive material may include one or more layers each having one or more materials selected from a group of molybdenum (Mo), silver (Ag), aluminum (Al), gold (Au) and nickel (Ni).

Note that the terms “bump electrode” and “pad electrode” are referred to any suitable conductive structures formed on substrates and may be made of any suitable material(s) with any suitable shape(s) without limitations. The terms “bump electrode” and “pad electrode” may be interchangeably used, as disclosed herein.

To provide the second substrate 130 on the resin gel 122, an aligning process may be performed to align the pad electrode 115 located within the resin gel 122 with a corresponding bump electrode 135 on the second substrate 130. After the aligning process, a preliminary pressing process may be performed to attach the second substrate 130 with the resin gel 122, and thus with the panel substrate 110 of the display panel. For example, the preliminary pressing process may at least remove air bubbles between the second substrate 130 and the resin gel 122 such that the second substrate 130 and the resin gel 122 are in direct contact with one another.

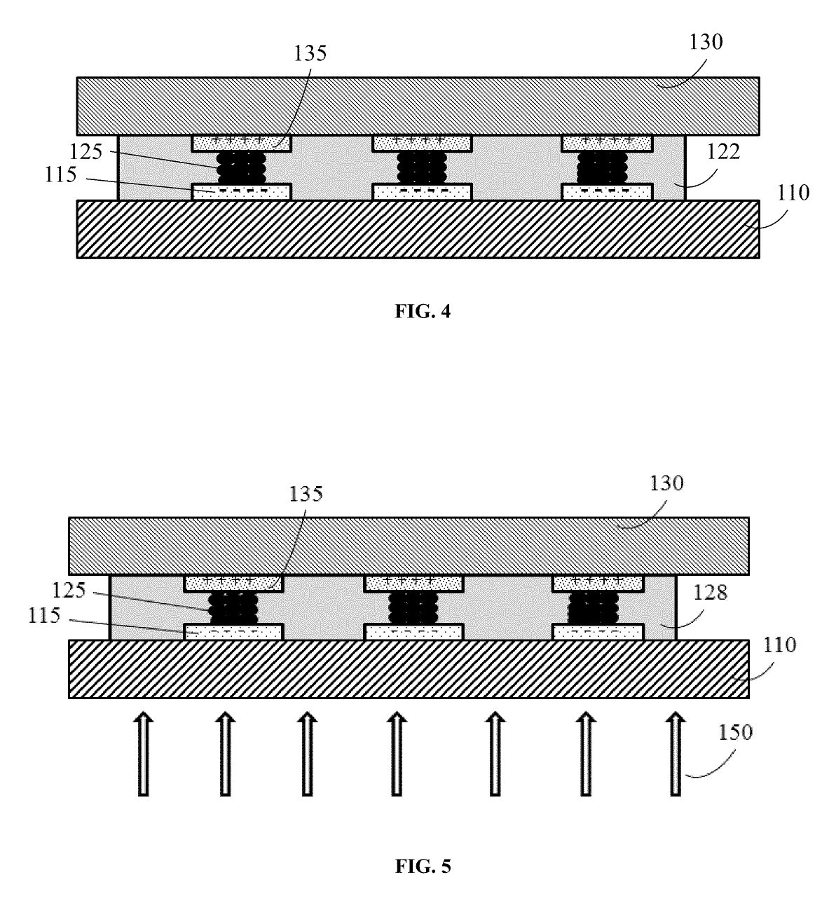

In FIG. 4, an electric field is generated between the pad electrodes 115 and the bump electrodes 135 using peripheral circuits. By using the electric field, the conductive particles 125 are aggregated and connected with one another in a direction according to the electric field to bridge the pad electrodes 115 with the bump electrodes 135, and thus to provide a conduction path there-between.

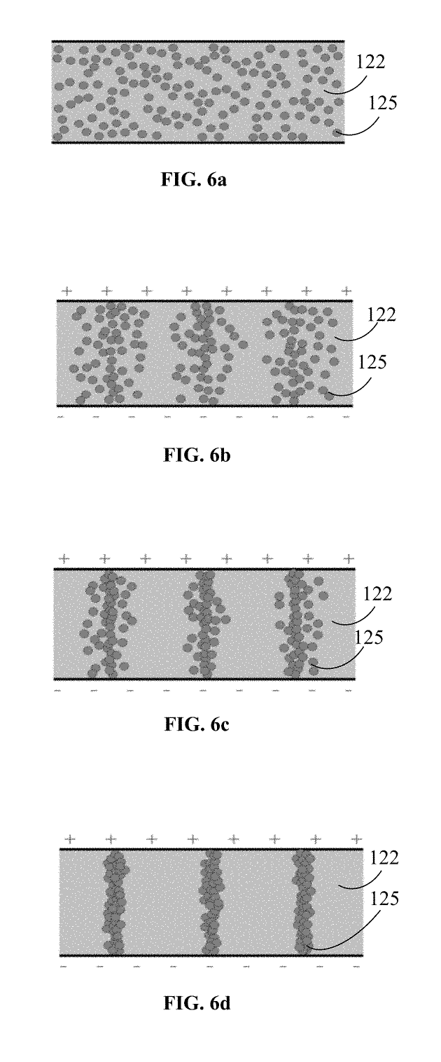

FIGS. 6a-6d illustrate movement of conductive particles under an electric field between a panel substrate and a second substrate in accordance with various embodiments of present disclosure.

In FIG. 6a, prior to applying the electric field, conductive particles 125 are randomly or uniformly disposed in the resin gel 122.

In FIG. 6b, when the electric field is generated, the conductive particles 125 may be polarized to generate electric dipoles to form an electric dipole moment, and then may move together under the electric field in a region between the pad electrode 115 of the panel substrate and the bump electrode of the second substrate. The conductive particles may aggregate and start interacting with one another.

In FIG. 6c, under the electric field, the conductive particles 125 may be aligned or connected in chains along the direction of the electric field generated between the pad electrodes 115 of the panel substrate 110 and the bump electrodes 135 of the second substrate 130 in the resin gel 122.

Generally, conductive particles in a liquid-like gel may be characterized as follows.

$$P = α E , \\ α = 4 {πα}^{3} Re ( {ɛ}_{1} ) \frac{{ɛ}_{2} - {ɛ}_{1}}{{ɛ}_{2} + {ɛ}_{1}} .$$

where, α is the polarization ratio, E is strength of the electric field, Re is a radius of the particles, ε₂ is the dielectric constant of the particles, and ε₁ is the dielectric constant of the resin gel.

Therefore, the interaction energy between two polarized spherical conductive particles under the electric field in the resin gel may be characterized as follows.

U(r,θ)=−(μ²/ε₁r³)(3cos²θ−1), r≧2α·

where, r is the distance vector between the particles, θ is an acute angle between the distance vector r and the electric field strength E, and μ is induced dipole moment of the particles. When θ<54.7°, the particles attract each other; and when θ>54.7°, the particles repel each other.

Under the electric field, the conductive particles may interact with one another. When θ=54.7°, in a “virtue” cone, which is axially centered in a direction along the electric field and having a 20 apex angle, conductive particles at the apex of and within the cone may attract each other, while conductive particles at the apex and outside of the cone may repel each other.

In FIG. 6d, under the applied electric field, the conductive particles 125 may be aligned and connected with one another to provide a significant conduction path between the pad electrodes 115 of the panel substrate 110 and the bump electrodes 135 of the second substrate 130 in the resin gel 122.

In a certain embodiment, the conductive particles 122 dispersed in the resin gel 122 may have a particle concentration ranging from about 5,000 pcs/cm³ to about 10,000 pcs/mm³ of the total resin gel. In various embodiments, the applied electric field strength E may be controlled in a range from about 0.5 KV/mm to about 2 KV/mm.

Also referring back to FIG. 4, under the electric field, the bump electrodes 135 of the second substrate 130 may thus be electrically connected to the pad electrodes 115 of the panel substrate 110 through the aligned and connected conductive particles 125 in the resin gel 122.

In FIG. 5, a UV-curing process 150 may be performed to cure the resin gel 122 to form a resin layer 128 to thus bond the panel substrate 110 and the second substrate 130. For example, the UV-curing process may be performed at room temperature. The curing process may be performed at a wavelength ranging from about 100 nm to about 400 nm, for example, at a wavelength of about 365 nm.

Once cured, the resin layer 128 may be stably maintained at room temperature without further reactions. Because the resin layer is made of an insulation material, the resin layer may insulate adjacent pad electrodes 115 or adjacent bump electrodes 135.

Because the conductive particles 125 provide a conduction path between the panel substrate 110 and the second substrate 130, the second substrate 130 may receive an external control signal, e.g., from a printed circuit board (PCB), to control driving of the display panel having the panel substrate 110, and then apply the control signal to the display panel. In some cases, the second substrate 130 may include a driving circuit unit that generates various control signals.

Accordingly, upon completion of the UV curing process, the panel substrate 110 and the second substrate 130 are bonded with each other. The UV curing process may be used to solidify the resin gel and to perform bonding process between the panel substrate 110 and the second substrate 130.

In various embodiments, the conductive particles 125, which are aligned and connected to provide electrical conduction path between the panel substrate 110 and the second substrate 130, may be irregularly distributed or uniformly aligned in the resin layer 128. The conductive particles 125 and the resin layer 128 form an anisotropic conductive film (ACF) between the panel substrate 110 and the second substrate 130.

Thus, the resin layer 128 may serve to physically couple the second substrate 130, such as a COF or FPC substrate, with the display panel, while the randomly or uniformly connected conductive particles 125 in the resin layer 128 may serve to electrically connect the COF or FPC substrate with the display panel.

In one embodiment, electric conductivity of the anisotropic conductive film located between the display panel and the COF or FPC substrate may be in proportion to the number of either the bump electrodes or the panel electrodes.

As such, in a certain embodiment, the disclosed anisotropic conductive film may include aligned and connected conductive particles induced by an electric field in a liquid-like UV-curable gel. The conductive particles may be carbon-based particles uniformly or randomly distributed in the UV-curable gel. The conductive particles may be aggregated and connected in chains under an electric field to provide a conduction path. The liquid-like UV-curable gel may be coated on a panel bonding area of a display panel, followed by an aligning process and a preliminary pressing process between a COF or FPC substrate and the panel substrate. By using an external circuit, an electric field may be generated to aggregate, align, and connect the conductive particles to provide a conduction path. The liquid-like UV-curable gel may then be cured and solidified to complete the bonding process.

It should be noted that the disclosed bonding process by the UV curing process is performed at room temperature, e.g., around 20-25° C., without using a heating process. This can avoid miss-aligned COF substrate caused due to expansion of the COF substrate under heating. In addition, connected conductive particles arranged in chains along the direction of the electric field may avoid a short circuit in a transverse direction of the electric field. This can avoid uneven blasting issues generated by conventional conductive particles. Electrical conduction may be improved. The disclosed method provides a low-temperature bonding process with improved yield.

Various embodiments also provide the display panel. The display panel may include a display panel having a panel substrate, a driving unit having an exemplary COF substrate for controlling driving of the display panel, and an anisotropic conductive film (ACF) including aligned and connected conductive particles in a cured resin layer to electrically connecting the display panel and the driving unit. For example, the display device may include the bonding structure shown in FIG. 5.

The above detailed descriptions only illustrate certain exemplary embodiments of the present disclosure, and are not intended to limit the scope of the present disclosure. Those skilled in the art can understand the specification as whole and technical features in the various embodiments can be combined into other embodiments understandable to those persons of ordinary skill in the art. Any equivalent or modification thereof, without departing from the spirit and principle of the present disclosure, falls within the true scope of the present disclosure.

1-19. (canceled)

20. An anisotropic conductive film (ACF), comprising:
a resin gel; and
a plurality of conductive particles dispersed in the resin gel, and being aligned and connected, in response to an electric field, to form a conduction path in the resin gel.

21. The anisotropic conductive film according to claim 20, wherein:
the resin gel includes one or more materials selected from a group of epoxy acrylates, urethane acrylates, polyester acrylates, polyether acrylates, acrylated polyacrylic resin, unsaturated polyester resin, and acrylate monomers.

22. The anisotropic conductive film according to claim 20, wherein:
the conductive particles include carbon-based particles selected from a group of carbon black, carbon fibers, and carbon nanotubes.

23. The anisotropic conductive film according to claim 20, wherein:
the conductive particles are in a form of cones, pyramids, shafts, pillars, wires, rods, needles, and spheres.

24. The anisotropic conductive film according to claim 20, wherein:
the conductive particles have a circular or polygonal cross-section.

25. The anisotropic conductive film according to claim 20, wherein:
the conductive particle includes an insulation material core, and a metal material encapsulating the insulation material core, and
the metal material includes one or more metal elements selected from a group of Cu, Ag, Ni, Ti, Al, and Au.

26. The anisotropic conductive film according to claim 20, wherein:
the conductive particles are dispersed in the resin gel having a particle concentration ranging from about 5,000 pcs/mm³ to about 10,000 pcs/mm³.

27. A bonding structure, comprising the anisotropic conductive film according to claim 20, wherein:
the resin gel is configured between a first substrate and a second substrate,
the first substrate has pad electrodes thereon,
the second substrate has bump electrodes thereon, and
the plurality of conductive particles in the resin gel provides the conduction path in the resin gel between one pad electrode of the first substrate and one bump electrode of the second substrate.

28. The bonding structure according to claim 27, wherein the resin gel is UV-curable to bond the first substrate with the second substrate.

29. The bonding structure according to claim 27, wherein:
the one bump electrode faces the one pad electrode face and is aligned with the one pad electrode.

30. A display panel comprising the bonding structure according to claim 27, wherein:
the display panel is used in a liquid crystal display, a field emission display, a plasma display, and an organic light emitting diode display device.

31. The display panel according to claim 30, wherein:
the first substrate is a panel substrate, and
the pad electrodes are located in a panel bonding area of the panel substrate.

32. The display panel according to claim 30, wherein:
the second substrate is a chip-on-film (COF) substrate or a flexible printed circuit (FPC) substrate.

33. A method for forming a bonding structure, comprising:
providing a first substrate having pad electrodes thereon;
coating a resin gel, containing conductive particles therein, to cover the pad electrodes on the first substrate;
providing a second substrate, having bump electrodes thereon, on the resin gel, wherein the bump electrodes face the pad electrodes; and
applying an electric field to align and connect the conductive particles in the resin gel to form a conduction path between the bump electrodes and the pad electrodes.

34. The method according to claim 33, further including:
curing the resin gel to bond the first substrate with the second substrate by a UV-curing process.

35. The method according to claim 34, wherein:
the UV-curing process is performed at a room temperature and at a wavelength ranging from about 100 nm to about 400 nm.

36. The method according to claim 33, wherein:
the first substrate is a panel substrate,
the pad electrodes are located in a panel bonding area of the panel substrate, and
the resin gel containing the conductive particles is coated on the panel bonding area to cover the pad electrodes.

37. The method according to claim 33, wherein the step of providing a second substrate having bump electrodes thereon on the resin gel further includes:
aligning the bump electrodes with the pad electrodes, and
performing a preliminary pressing process, such that the second substrate and the resin gel are in direct contact.

38. The method according to claim 33, wherein:
the electric field is controlled to have an electric field strength in a range from about 0.5 KV/mm to about 2 KV/m
